(19) United States
(12) Patent Application Publication
(10) Pub. No.: US 2007/0046308 A1
(43) Pub. Date: Mar. 1, 2007

(54) Test modes for a semiconductor integrated circuit device

(76) Inventors: Ronald Baker, Raleigh, NC (US); George W. Alexander, Durham, NC (US)

Correspondence Address: EDELL, SHAPIRO & FINNAN, LLC, 1901 RESEARCH BLVD., SUITE 400, ROCKVILLE, MD, 20850, US

(21) Appl. No.: 11/211,743

(22) Filed: Aug. 26, 2005

(51) Int. Cl. G01R 31/02

(52) U.S. Cl. 324/761

(57) ABSTRACT

A semiconductor integrated circuit device is provided including a switch to selectively supply a test signal to a pin on the integrated circuit device in response to a switch control signal. A control circuit is also provided to generate the switch control signal.

### FIELD OF THE INVENTION

This invention relates to semiconductor devices, and more specifically to test modes of semiconductor integrated circuit devices.

### BACKGROUND OF THE INVENTION

In the field of semiconductor integrated circuits (ICs), many tests are performed to insure accurate performance of the devices. Functional testing is done at various stages including testing functionality via pins on the integrated circuit device. Test devices are used to perform the testing operations. Test device resources such as drivers, pins, and circuitry, are required for performing these tests.

For example, when testing the functionality of a pin such as the on-die termination (ODT) pin of a semiconductor integrated circuit device, a driver pin on a test device is required to supply a voltage signal having a logic “high” level to the ODT pin in order to set up the test conditions. FIG. 1 shows an example of an ODT pin arrangement. The function of the ODT pin is to serve as a control pin to enable on-die termination resistors for the I/O pins. A single termination resistor is shown at reference numeral 12 and is connected to a variety of I/O pins and to a DRAM input buffer 14. Only a single termination resistor 12 is shown for simplicity, but it is to be understood that there is a network of resistors for each I/O pin on the chip. When the ODT pin is disabled (not connected to a voltage), the resistance of the termination resistor 12 is open-circuit (or infinite resistance). When the ODT pin is enabled (connected to a suitable voltage, e.g., ½ VDDQ), the resistors in all of the resistor networks for the I/O pins on the chip are enabled such that they have a desired resistance value across them. For example, the resistance across the termination resistor 12 should be at a particular value. It is this resistance that is to be measured during the test mode.

Test devices have a limited number of resources (e.g., pins, circuitry, etc.). Therefore, it is generally desirable to reduce the number of test device resources required for testing. If the number of test device resources can be sufficiently reduced, then a single test device can simultaneously test multiple ICs. More specifically, if the resource requirements for a test device can be reduced, then the number of parallel devices under test (DUTs) for a single test device can be increased. Similarly, the complexity of the test device interface can be reduced.

### SUMMARY OF THE INVENTION

A semiconductor integrated circuit device is provided including a switch to selectively supply a test signal to a pin on the integrated circuit device in response to a switch control signal. A control circuit is also provided to generate the switch control signal.

### BRIEF DESCRIPTION OF THE DRAWINGS

FIG. 1 is a block diagram showing the Prior Art.

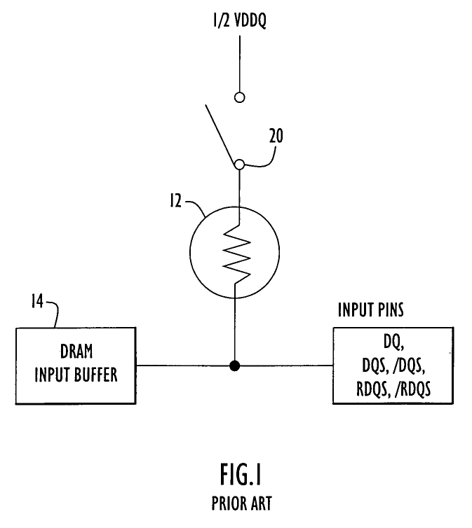

FIG. 2 is a block diagram generally showing an embodiment of the invention.

FIG. 3 is a block diagram showing an embodiment of the invention.

FIG. 4 is a schematic diagram of the embodiment shown in FIG. 3.

FIG. 5 is a block diagram showing another embodiment of the invention.

FIG. 6 is a schematic diagram of the embodiment shown in FIG. 5.

FIG. 7 is a timing diagram for the embodiment shown in FIG. 5.

FIG. 8 is a block diagram of still another embodiment of the invention.

FIG. 9 is a schematic diagram of the embodiment shown in FIG. 8.

FIG. 10 is a flow chart showing operation of the embodiments of this invention.

### DETAILED DESCRIPTION

In order to facilitate a discussion of the invention, embodiments of the invention will be described with respect to a particular pin on an integrated circuit device. Specifically, the invention will be described with reference to an on-die termination (ODT) pin of a semiconductor memory device. However, it is to be understood that the present invention is not limited to this embodiment and that alternative equivalent structures and embodiments are contemplated within the scope of the invention.

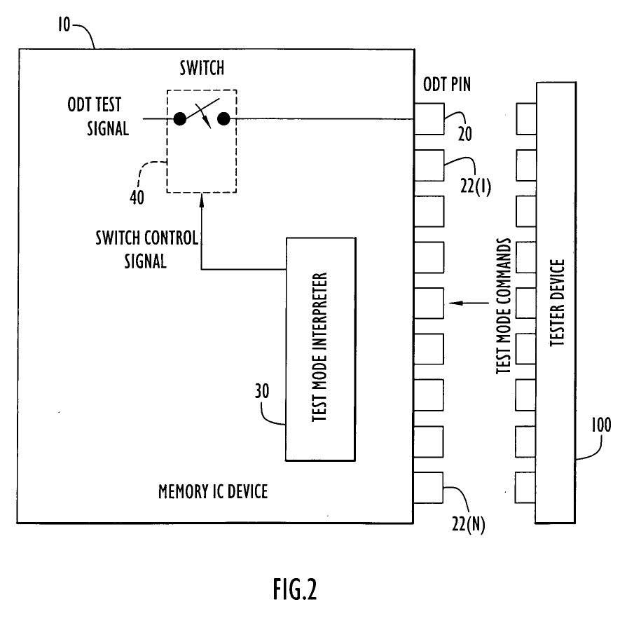

Referring first to FIG. 2, a semiconductor memory integrated circuit (IC) device is shown at reference numeral 10. The IC device 10 includes an ODT pin 20, as well as numerous other pins 22(1) to 22(N). The function of the ODT pin 20 is to enable on-die termination resistors for the various input/output (I/O) pins on the integrated circuit. The IC device 10 also includes a test mode interpreter circuit 30 and a switch 40. The test mode interpreter circuit 30 is a decoder circuit that decodes a test mode command supplied to the integrated circuit from a test device 100 during a test procedure, and generates one or more control signals to configure the IC device for the test mode. The switch 40 has a first terminal connected to a control or test signal such as an ODT test signal and a second terminal connected to the ODT pin 20. In response to a particular test mode command, the test mode interpreter circuit 30 generates a switch control signal. The switch 40 is responsive to the switch control signal to connect the ODT pin to the on die termination test signal source. The source of the test signal for the pin under test includes any suitable source on the IC device for performing the desired test.

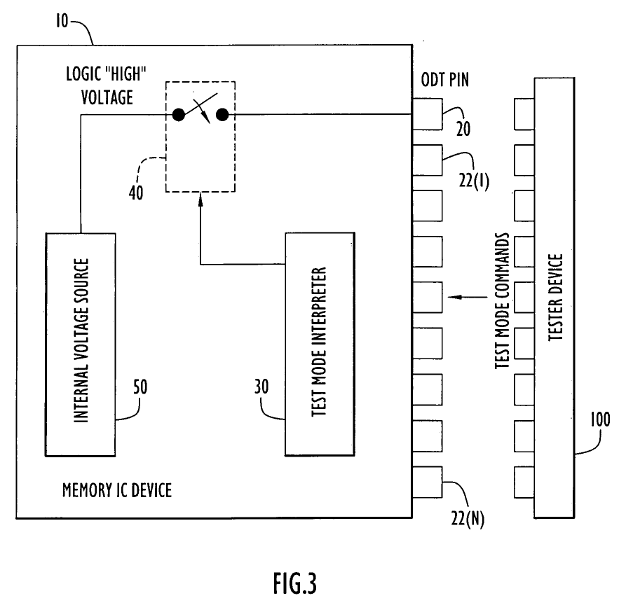

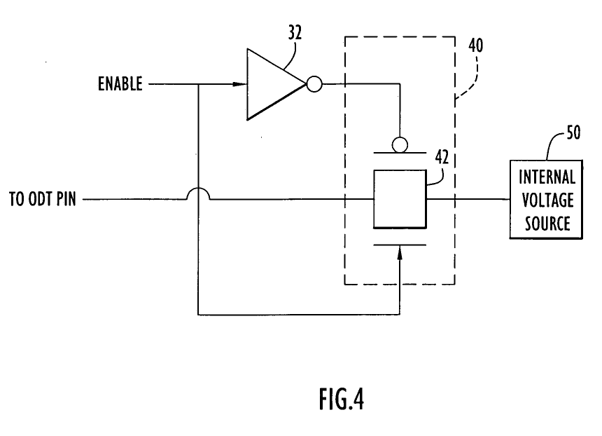

Turning to FIGS. 3 and 4, an internal ODT enable test mode according to an embodiment of the invention will be described. This embodiment is useful during a test mode in which static test measurements are made on termination resistors in the IC device 10. An internal voltage source 50 in the IC device 10 is connected to the first terminal of the switch 40. The internal voltage source 50 may be any voltage source on the IC that has a voltage level greater than or equal to a threshold necessary to achieve the desirable resistance across termination resistors. The test mode interpreter circuit 30 is responsive to this particular test mode command to generate a switch control signal that causes the switch 40 to connect the voltage from the internal voltage source 50 to the ODT pin 20. Again, this embodiment is useful for making measurements under static (DC) signal conditions since the internal voltage source 50 supplies a fixed voltage. Rather than dedicate a pin on the test device 100 for such a simple test, this arrangement uses an internal voltage source already present on the IC device 10 to supply the necessary voltage to the ODT pin for setting up the testing conditions. This test mode illustrates an embodiment of the invention where an internal or on-chip resource is used to perform the test operation.

As shown in FIG. 4, one exemplary implementation of the switch 40 is a transfer gate 42 consisting of n-type field effect transistors (FETs) and p-type FETs connected at the source and drain. The switch control signal generated by the test mode interpreter circuit 30 is shown as an Enable signal that is connected to a first gate terminal of the transfer gate 42, and to an inverter 32 whose output is connected to a second gate terminal of the transfer gate 42. The internal voltage source 50 is connected to an input terminal of the transfer gate 42 and the ODT pin 20 is connected to an output terminal of the transfer gate 42. When the Enable signal is a logic high voltage, the transfer gate 42 closes thereby connecting the ODT pin 20 to the internal voltage source 50. Otherwise, the transfer gate 42 is open, disconnecting the ODT pin 20 from the internal voltage source 50.

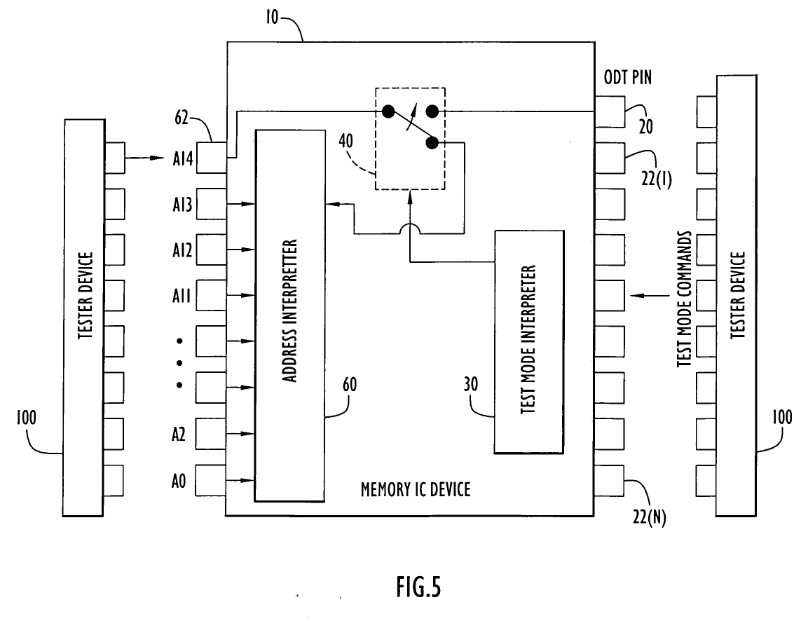

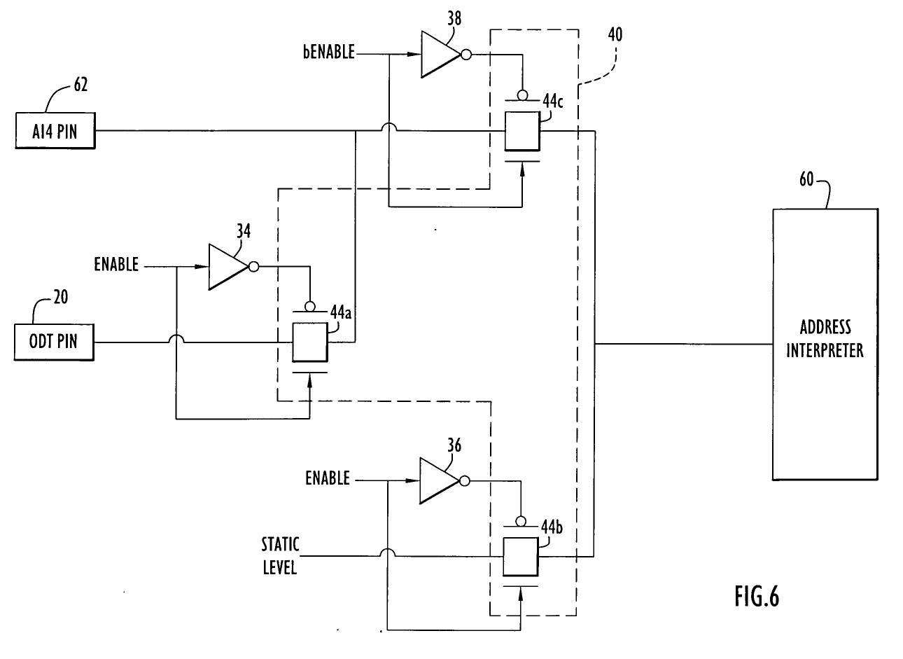

Referring now to FIGS. 5 and 6, an embodiment is shown for a dynamic ODT enable test mode. During a dynamic ODT test mode, the ODT pin 20 is toggled up (enabled) and down (disabled) to test set-up time and hold-time of the termination resistors. This type of testing is useful to ensure that the termination resistors switch in and out properly. The IC device 10 includes an address interpreter 60 that is used to decode the address signals supplied to address pins A0 to A14, for example, when accessing memory cells. During a dynamic ODT test, only a few memory cells are addressed, so all the address pins are not needed to address these memory cells. One of the address pins, e.g., address pin A14, is selected to serve as a means to supply a dynamic (e.g., multi-level voltage) ODT control or test signal to the ODT pin. The particular address pin is one that is known to be available during the dynamic ODT tests.

The test device 100 responds to this particular test mode command to generate a switch control signal that causes the switch 40 to connect the ODT pin 20 to one of the address pins on the IC device 10, for example, to address pin A14. In addition, the switch 40 disconnects the address pin A14 from the address interpreter 60 when connecting the address pin A14 to the ODT pin 20 during tests that require dynamic ODT pin states. The ODT test signal is then supplied from a pin on the test device 100 to the address pin A14 that is connected to the ODT pin 20 via the switch 40. The test device 100 supplies a desired waveform for the ODT test signal to externally manipulate the ODT pin with a desired speed and pattern. The test signal is any signal suitable for performing the desired test. The default setting of the switch 40 is such that the pin A 14 is connected to the address interpreter 60 for normal operation when the particular (dynamic ODT) test mode is not activated. This embodiment of the invention also utilizes on-chip resources to perform the test operation.

FIG. 6 illustrates one example of an implementation for switch 40 in connection with the embodiment of FIG. 5. Switch 40 comprises three transfer gates 44a, 44b and 44c (similar to the transfer gate shown in FIG. 4). Transfer gate 44a is connected between the ODT pin 20 and the particular address pin 62. Transfer gate 44b is connected between a voltage source (not shown) and the address interpreter 60. Transfer gate 44c is connected between the particular address pin 62, e.g., address pin A14, and the address interpreter 60. The switch control signal produced by the test mode interpreter circuit 30 in this embodiment consists of an Enable signal and a bEnable signal. The Enable signal is connected directly to a first gate terminal of transfer gate 44a, and to a second gate terminal of transfer gate 44a via an inverter 34. In addition, the Enable signal is connected directly to a first gate terminal of transfer gate 44b and to a second gate terminal of transfer gate 44b via the inverter 36. The bEnable signal is connected directly to the n-type terminal of transfer gate 44c and to the p-type terminal of transfer gate 44c via the inverter 38. When the Enable signal is a logic high voltage, the switch 44a closes thereby connecting the ODT pin 20 to the address pin A14. The switch 44c opens in response to the low voltage level of bEnable to disconnect the address pin A 14 from the address interpreter circuit 60. In addition, when the Enable signal is high, the switch 44b closes to connect a static voltage to the A14 pin input to the address interpreter 60 during the period of time that the A 14 pin is connected to the ODT pin 20 for the dynamic test mode. When the bEnable signal is high and the Enable signal is low, the switch 44c closes and the address pin A14 is connected to the address interpreter circuit 60 for normal use of the address pin A 14. The transfer gate 44b is provided so that the A 14 address pin input to the address interpreter 60 does not float during the time interval that the A 14 pin is connected to the ODT pin during the dynamic test mode. However, the A 14 pin input to the address interpreter 60 could be left floating.

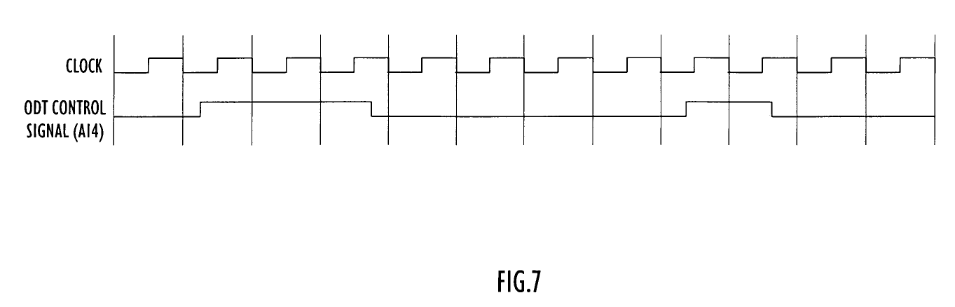

An example of a waveform for the ODT test signal is shown in FIG. 7. The ODT test signal changes between a “high” voltage level and a “low” voltage level, and remains at these respective levels for time durations that are chosen to perform suitable measurements on the termination resistors. This is only one example of a possible multi-level voltage waveform useful to toggle the termination resistors.

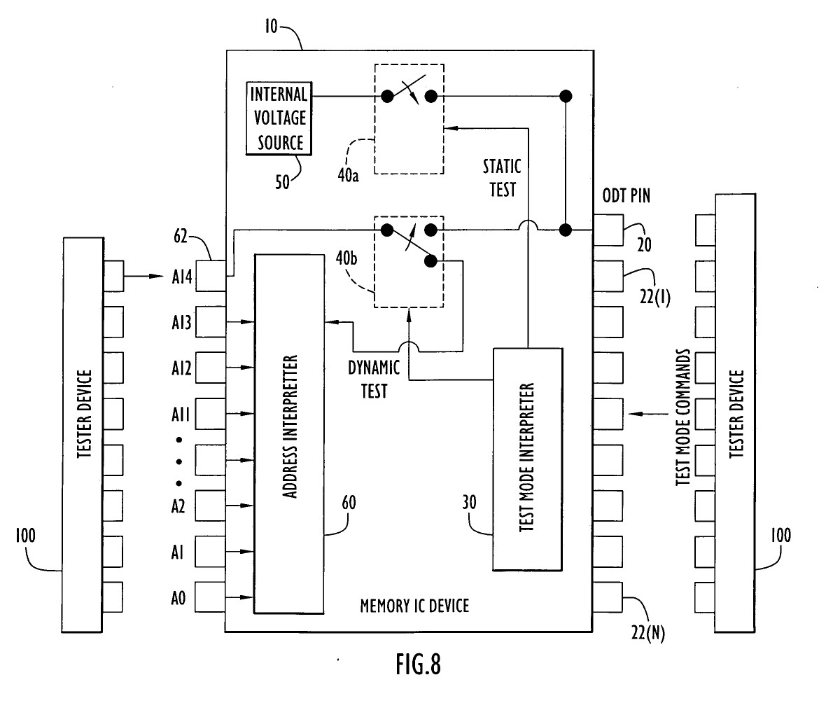

FIG. 8 illustrates another embodiment of the invention. A memory IC device 10 is configured to accommodate two types of test modes. More specifically, the IC device 10 includes two switches to facilitate testing in two modes. A first switch is used for a test mode where the test signal is supplied by an on-chip signal source, and a second switch is used for a test mode where the test signal is supplied by an external device to a pin required for normal operation of the IC device, but available to receive the test signal during a test mode. In the example shown in FIG. 8, the memory IC device 10 employs a configuration for both the static ODT pin test mode and dynamic ODT pin test mode. To this end, the device 10 comprises two switches 40a and 40b. Switch 40a connects the ODT pin 20 to an internal voltage source 50 during a static ODT test. Switch 40b connects the ODT pin 20 to an unused address pin, e.g., address pin A14, during a dynamic ODT test. The same test device 100 may be used for both tests, or a different test device may be used for each test. The test mode interpreter circuit 30 responds to the test mode commands supplied by the test device 100 to control either switch 40a or switch 40b, depending on which test mode command is supplied by the test device. The switches 40a and 40b may be implemented by a simple transistor. Any suitable switching device may be used to perform the switching operations.

The test mode interpreter circuit 30 is responsive to a first test mode command (static test mode command) supplied to the integrated circuit to control the switch 40a to connect the ODT pin 20 to the voltage source 50, and is responsive to a second test mode command (dynamic test mode command) supplied to the integrated circuit to control the switch 40b to connect the ODT pin 20 to a particular pin (e.g., pin A14) on the integrated circuit device that receives a test signal supplied as a voltage waveform that changes between levels for dynamic testing conditions of the termination resistors. The test signal is any signal suitable for performing the desired test.

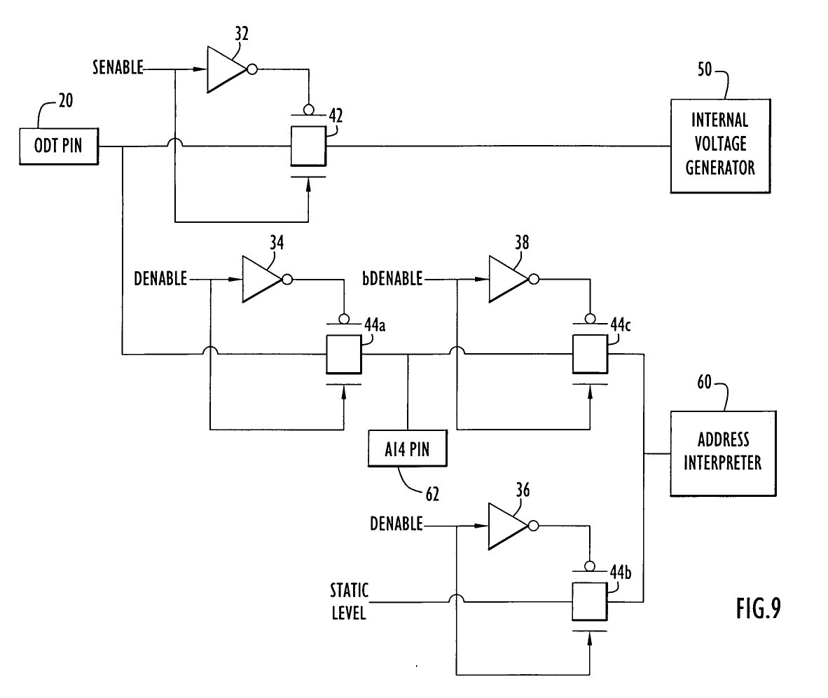

FIG. 9 illustrates an example of an implementation of the switches 40a and 40b for the embodiment shown in FIG. 8. FIG. 9 essentially combines the circuitry shown in FIGS. 4 and 6. There are two sets of switch control signals: SEnable (Static Enable) for the static test mode conditions; and DEnable (Dynamic Enable) and bDEnable for the dynamic test mode conditions. To connect the ODT pin 20 to an internal voltage source for static test mode conditions, the SEnable (Static Enable) signal is at a logic high voltage, causing switch 42 to close. When SEnable is high, DEnable is low and bDEnable is high so that the A14 pin is connected to the address interpreter 60 for normal addressing operations. For dynamic test mode conditions, DEnable is high thereby closing switch 44a to connect address pin A 14 to the ODT pin 20 and bDEnable is low opening switch 44c and disconnecting the address pin A14 from the address interpreter 60. In addition, when DEnable is high, switch 44b closes to connect a static level to address interpreter 60. When bDEnable is high, the address pin A14 is connected to the address interpreter for normal addressing operations.

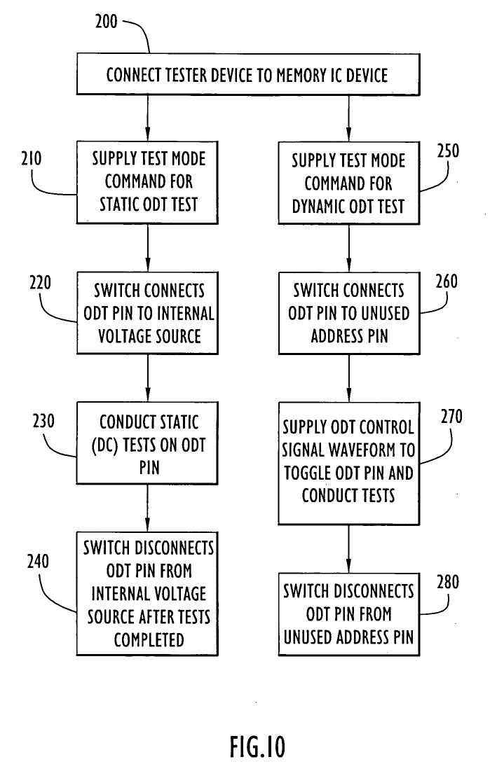

FIG. 10 illustrates a flow chart for the static and dynamic ODT test modes. A different test device may be used for the static test mode and dynamic test mode, or the same test device may be used for both test modes. In step 200, a test device 100 is connected to the memory IC device 10. The path on the left side corresponds to the static ODT test mode. In step 210, the test device 100 supplies a test mode command or commands to set up the IC device for the static ODT test. In step 220, the test mode interpreter circuit 30 responds to the static test mode command and generates the switch control signal that causes the switch 40 to connect the ODT pin 20 to the internal voltage source 50. Next, in step 230, the test device conducts the static (DC) tests on the ODT pin. After these tests are completed, the test mode interpreter circuit 30 responds to a command from the test device 100 to control the switch 40 to disconnect the ODT pin from the internal voltage source 50.

The path on the right side of FIG. 10 is for the dynamic ODT test mode. In step 250, the test device 100 supplies to the IC device 10 test mode commands for the dynamic ODT test mode. In step 260, the test mode interpreter circuit 30 responds to the dynamic test mode command and generates the switch control signal that causes the switch 40 to connect the ODT pin 20 to a particular address pin on the IC device that is not being used for accessing memory cells during the dynamic ODT test mode. In step 270, the test device 100 supplies a multi-level (e.g., two levels) voltage waveform to the unused address pin, which is in turn connected by the switch 40 to the ODT pin 20, to toggle the termination resistors for the measurements to be made during the test. When the dynamic ODT test mode is complete, the test mode interpreter circuit 30 responds to a command from the test device 100 to disconnect the ODT pin 20 from the unused address pin in step 280.

According to the present invention, internal resources of an IC device are utilized to set up and perform testing operations which results in increased parallelism in testing operations. According to the present invention, a switch is provided on the IC device to connect an internal resource to a pin to be tested to supply the pin with a test signal. The test signal from the internal resource is a signal suitable for performing the desired test. Additionally or alternatively, a switch is provided on the IC device to connect an existing pin, required during normal operation of the IC device but available to receive a test signal during the test mode, to the pin to be tested. The test signal supplied to the pin to be tested via the existing pin is a signal suitable for performing the desired test.

Although the present invention and its advantages have been described in detail, it should be understood that various changes, substitutions and alterations can be made herein without departing from the spirit and scope of the invention as defined by the appended claims.

What is claimed is:

1. A semiconductor integrated circuit device having a pin to be tested, the semiconductor integrated circuit device comprising:
a. a switch to selectively supply a test signal to the pin in response to a switch control signal; and
b. a control circuit arranged to generate the switch control signal.

2. The semiconductor integrated circuit device of claim 1, wherein the test signal is supplied by a voltage source on the semiconductor integrated circuit device that outputs a voltage signal having a level sufficient for testing the pin.

3. The semiconductor integrated circuit device of claim 1, wherein the test signal is supplied by an external device to a particular pin on the semiconductor integrated circuit device, wherein the switch is responsive to the switch control signal to connect the pin to the particular pin during a test mode, wherein the particular pin is available for use during the test mode.

4. The semiconductor integrated circuit device of claim 3, wherein the particular pin is an address pin that is available for use during the test mode.

5. The semiconductor integrated circuit device of claim 4, wherein the switch comprises first and second transistor gate devices, wherein the first transistor gate device connects the pin to the particular pin during the test mode and the second transistor gate connects a static voltage to an address interpreter circuit during the test mode.

6. The semiconductor integrated circuit device of claim 3, wherein the test signal switches between at least two levels to test the pin during the test mode.

7. The semiconductor integrated circuit device of claim 1, wherein the pin to be tested is an on-die termination pin.

8. A semiconductor integrated circuit device having a pin to be tested, the semiconductor integrated circuit device comprising:
a. a first switch to selectively supply a first test signal to the pin in response to a first switch control signal;
b. a second switch to selectively supply a second test signal to the pin in response to a second switch control signal; and
c. a control circuit arranged to generate the first switch control signal during a first mode of operation of the semiconductor integrated circuit device and the second switch control signal during a second mode of operation of the semiconductor integrated circuit device.

9. The semiconductor integrated circuit device of claim 8, wherein the first test signal is supplied by a voltage source on the semiconductor integrated circuit device that outputs a voltage signal having a level sufficient for testing the pin.

10. The semiconductor integrated circuit device of claim 9, wherein the first switch is responsive to the first switch control signal to connect the pin to the voltage source during the first mode of operation.

11. The semiconductor integrated circuit device of claim 10, wherein the second test signal is supplied by an external device to a particular pin on the semiconductor integrated circuit device.

12. The semiconductor integrated circuit device of claim 11, wherein the second switch is responsive to the second switch control signal to connect the pin to the particular pin during the second mode of operation.

13. The semiconductor integrated circuit device of claim 11, wherein the particular pin is an address pin that is available for use during the second mode of operation.

14. The semiconductor integrated circuit device of claim 13, wherein the second switch comprises first and second transistor gate devices, wherein the first transistor gate device connects the pin to the particular pin during the test mode and the second transistor gate device connects a static voltage to an address interpreter circuit during the test mode.

15. The semiconductor integrated circuit device of claim 11, wherein the second test signal switches between at least two levels to test the pin during the second mode of operation.

16. The semiconductor integrated circuit device of claim 8, wherein the pin to be tested is an on-die termination pin.

17. A semiconductor integrated circuit device having a pin to be tested, the semiconductor integrated circuit device comprising:
a. first switching means for selectively supplying a first test signal to the pin in response to a first switch control signal; and
b. control means for generating the first switch control signal.

18. The semiconductor integrated circuit device of claim 17, further comprising means for generating the first test signal, wherein the first switching means is responsive to the first switch control signal to connect the pin to the generating means during a first mode of operation.

19. The semiconductor integrated circuit device of claim 18, further comprising second switching means for selectively supplying a second test signal to the pin in response to a second switch control signal, the control means generating the second switch control signal during a second mode of operation.

20. The semiconductor integrated circuit device of claim 19, wherein the second test signal is supplied by an external device to a particular pin on the semiconductor integrated circuit device, wherein the second switching means is responsive to the second switch control signal to connect the pin to the particular pin during the second mode of operation.

21. The semiconductor integrated circuit device of claim 20, wherein the second switching means comprises first and second transistor gate devices, wherein the first transistor gate device connects the pin to the particular pin during the test mode and the second transistor gate devices connects a static voltage to an address interpreter circuit during the test mode.

22. The semiconductor integrated circuit device of claim 20, wherein the second test signal switches between at least two levels to test the pin during the second mode of operation.

23. The semiconductor integrated circuit device of claim 17, wherein the pin to be tested is an on-die termination pin.

24. A method for testing an integrated circuit device having an internal voltage source, comprising: connecting a pin to the internal voltage source to test the pin in response to a first test command in a first test mode.

25. The method of claim 24, wherein connecting comprises connecting the pin to a particular pin on the integrated circuit in response to a second test command, and further comprising supplying the voltage signal from an external device to the particular pin, wherein the particular pin is available for use during a second test mode.

26. The method of claim 24, wherein connecting comprises connecting the pin to an address pin that is available for use during a second test mode, and further comprising supplying the voltage signal from an external device to the address pin.

27. The method of claim 26, further comprising changing a level of the voltage signal that is connected to the address pin during the second test mode.

28. The method of claim 27, wherein changing comprises toggling the voltage signal between a high value and a low value according to a desired timing pattern.
